(19) United States
(12) Patent Application Publication
(10) Pub. No.: US 2013/0035819 A1
(43) Pub. Date: Feb. 7, 2013

(54) HIGH-VOLTAGE SYSTEM FOR A MOTOR VEHICLE AND METHOD FOR DIAGNOSING A HIGH-VOLTAGE SYSTEM FOR A MOTOR VEHICLE

(71) Applicant: Norbert Wolft, Lenting (DE)

(72) Inventor: Norbert Wolft, Lenting (DE)

(73) Assignee: AUDI AG, Ingolstadt (DE)

(21) Appl. No.: 13/641,570

(22) PCT Filed: Apr. 9, 2011
(86) PCT No.: PCT/EP2011/001775

§ 371 Date: Oct. 16, 2012

(30) Foreign Application Priority Data
Apr. 17, 2010 (DE) 10 2010 015 312.5

(51) Int. Cl. G01R 31/28; H02J 7/00

(52) U.S. Cl. 701/22

(57) ABSTRACT

The invention relates to a high-voltage system (1) for a motor vehicle (26), comprising a high-voltage battery (2) that supplies at least one load (4), in particular an inverter (5), by means of cables (3), wherein at least one switching means (8, 9, 11) is provided in order to disconnect the high-voltage supply, a capacitor (7) connected in parallel with the load (4), and a discharge circuit (12) for discharging the capacitor (7), said discharge circuit having a discharge resistor (13) and a discharge switching means (14) that closes the discharge circuit, wherein a diagnostic device having a measuring device (16) for measuring a voltage profile that describes the voltage profile on the capacitor (7), in particular during the discharge process (17), and a control device (15) for evaluating the voltage profile in regard to a malfunction of the high-voltage system (1) is provided.

The invention relates to a high-voltage system for a motor vehicle, including a cables high-voltage battery supplying at least one load, in particular an inverter, via cables, wherein at least one switching means for disconnecting the high-voltage supply is provided, a capacitor connected in parallel with the load, and a discharge circuit for discharging the capacitor with a discharge resistor and a discharge switching means closing the discharge circuit, and a method for the diagnosing such a high-voltage system.

It is nowadays customary, in particular in hybrid vehicles or electric vehicles, to use high-voltage batteries. Such high-voltage batteries may employ voltages greater than 60V, for example up to 300V. For example, motor vehicles with an electric motor are known, wherein the DC voltage of the high-voltage battery is initially converted with an inverter, in particular a pulse inverter, into an AC voltage, which is then used to operate the corresponding high-voltage systems in the motor vehicle; of course, other loads may in principle also be considered. A capacitor connected in parallel with the load, i.e. in particular with the inverter, is used (a so-called DC-link capacitor). Such a capacitor is charged with the high-voltage supply by using at least one switching means in the high-voltage battery.

A safety aspect has to be considered with voltages above 60 V, as they can cause an electric shock upon contact. Moreover, special protection rules apply regarding protection from contact with such voltages. Devices capable of controllably discharging the capacitor after disconnection of the high-voltage supply are known in the art. Such discharge circuits for discharging the capacitor include, for example, a discharge resistor and discharge switching means closing the discharge circuit. When the discharge switching means is closed, the charge of the capacitor can be controllably discharged via the discharge resistor, so that high-voltages no longer remain in the high-voltage system after disconnection of the high-voltage supply, which could pose a danger when touched.

Such a high-voltage system is known, for example, from DE 10 2008 012 418 A1, wherein a high-voltage system is provided for reliably checking contacting. However, additional hardware is required for measuring the current.

It would be important in such high-voltage system to diagnose in particular the functionality of the discharge circuit in order to minimize the danger to people. However, a complete diagnosis of the functionality of the discharge circuit without additional expensive hardware is not known in the art.

It is therefore an object of the invention to provide a high-voltage system and a method for diagnosing a high-voltage system capable of monitoring the functionality of the discharge circuit without adding complexity.

To solve this problem, a high-voltage system of the aforementioned type includes a diagnostic device with a measuring device for measuring a voltage profile describing the voltage profile across the capacitor and a control device for evaluating this voltage profile with respect to a malfunction of the high-voltage system.

It is therefore proposed to make a diagnosis by monitoring the temporal voltage profile on the capacitor itself, or another voltage profile which describes the voltage profile on the capacitor. The term “voltage profile describing the voltage profile on the capacitor” therefore also includes the voltage at the capacitor itself. During a discharge process, characteristic values of the voltage profile, in particular the response of the voltage profile to interventions made by the control device, can be readily determined, which will be discussed in more detail below. This is especially true when a high-voltage system with a ballast resistor for controllably charging the capacitance is used at a battery output.

Such ballast resistor is used for so-called “soft” switching on the high-voltage system. The DC-link capacitances, i.e. the capacitor, can be controllably charged via the ballast resistor. For example, high-voltage batteries with three switching means may be considered, with one switching means being associated with the cable without the ballast resistor, and one of the other two switching means being associated with the ballast resistor and the third of the other two switching means configured to connect the corresponding terminal of the battery directly to the cable. On the side of the high-voltage battery, the switching means on the cable without the ballast resistor is then closed first and thereafter the switching means associated with the ballast resistor. When a minimum voltage is reached, the switching means associated with the ballast resistor is opened again and the switching means connecting the cable directly with the pole of the battery is closed, thereby directly connecting the load to the high-voltage battery.

The ballast resistor is here typically smaller than the discharge resistor; the charging resistor may be, for example, in ohm range while the discharge resistor is in kilo-ohm range. In these situations, a diagnosis of the discharge circuit during the charging process is difficult or even impossible, so that the diagnosis can be performed according to the invention during the longer discharge process.

The present invention thus allows a diagnosis of the functionality of the discharge circuit, so that it can be determined, for example, whether a discharge of the capacitor is no longer possible at all, or whether the discharge is permanently activated, as will be discussed in more detail below,

With the high-voltage system according to the invention, a voltage describing the voltage profile across the capacitor is frequently measured anyway in conjunction with other functions, which means that the corresponding measuring device is already present. If the pre-existing control device is additionally configured, for example as a general control device for the high-voltage system or the supply of the motor vehicle, to perform the analysis of the voltage profile with respect to the functionality of the discharge circuit, i.e. in particular during the discharge operation, then additional devices are unnecessary—already existing hardware can therefore be used for an advantageous additional functionality. In a realistic embodiment, the control device (or a control device) may be configured to evaluate the voltage profile with respect to at least one additional function of the high-voltage system and/or the motor vehicle, and consequently an existing measuring device may be used. Advantageously, the measuring device may measure the voltage profile in an electric motor of the motor vehicle and/or the control device may be designed to control the electric motor of the motor vehicle as a function of the voltage profile. While such an arrangement of an electric motor by measuring voltages inside the electric motor itself is already known in the art, the present invention proposes to use the existing measurement and evaluation arrangement also for diagnosing the discharge circuit, taking advantage of the fact that the voltage profile in the electric motor corresponds to the voltage profile on the capacitor.

With respect to the evaluation of the voltage profile during the discharge process, after the high-voltage supply is disconnected, the control device may be configured to detect a malfunction when an elapsed time, after closing the discharge switching means and until reaching a limit voltage below the output voltage of the high-voltage battery voltage, exceeds a time threshold. In this manner, malfunctions of a first type can be detected wherein a discharge of the capacitor is no longer possible or is just too slow. When the discharge circuit operates correctly, the elapsed time after closing the discharge switching means until reaching a limit voltage, for example of 60 V, may be smaller than the time threshold. Such malfunction of the first type occurs, for example, when the discharge switching means cannot be closed. However, it should be noted at this point that the malfunction is also detected when the high-voltage battery can no longer be disconnected from the load, meaning that the switching means of the high-voltage battery can, for example, not be opened. To ensure that the malfunction occurs in the discharge circuit, it must be ascertained that the high-voltage battery has already opened the switching means. This state may be communicated from the high-voltage battery to the control device, for example, via a bus system, in particular a CAN bus. In this way, malfunctions in the high-voltage battery may be eliminated and the malfunction may be localized on the discharge circuit.

Advantageously, the control device may be configured to briefly interrupt the discharge process for a predetermined time by controlling the discharge switching means and for detecting a faulty operation when measuring at the time of the disconnect a voltage outside a threshold range around the voltage. In this way, a malfunction of the second type may be detected, namely that the discharge is permanently activated. This may be the case, for example, when the discharge switching means can no longer be opened. An attempt is then made to interrupt the discharge process for a brief predetermined time by controlling the discharge switching means accordingly with the control device. The resulting voltage following the (possibly perceived) opening of the discharge switching means is allowed to vary within the time period only in a maximum allowable threshold range, so that a normal function can be inferred.

In another embodiment of the present invention, a storage device for storing the number of malfunctions, in particular the number associated with the type of the malfunction, may be provided. Only successive malfunctions, or at least malfunctions occurring within a certain period of time, in particular malfunctions of a single type, may be added. Such an approach is particularly advantageous when the control device is configured to output an error message if a safety limit value is exceeded or a number of malfunctions has occurred. In this way, the diagnosis can be debounced by checking whether the malfunction occurred over several cycles. For example, the error message may be generated when a malfunction of a type has been detected during three consecutive cycles, Le. three discharge processes. This prevents a misdiagnosis by first storing malfunctions internally, with the control device only actually causing a corresponding error message to be outputted after debouncing.

Advantageously, the diagnostic device may be configured to perform an evaluation each time the high-voltage supply is disconnected, in particular at each deactivation of the ignition. The operation of the discharge circuit is thus continuously checked. The evaluation may be coupled, for example, with the presence of a signal at a specific terminal when the ignition key is moved to another position, and the like.

In addition to the high-voltage system, the invention also relates to a method for diagnosing a high-voltage system for a motor vehicle, especially for the inventive high-voltage system, comprising at least one high-voltage battery supplying a load, in particular an inverter, via cables, wherein at least one switching means for disconnecting the high-voltage supply is provided, a capacitor connected in parallel with the load, and the discharge circuit for discharging the capacitor with a discharge resistor, and discharge switching means closing the discharge circuit, wherein the method is characterized in that a voltage profile describing the voltage profile across the capacitor is measured, in particular during a discharge process, and is evaluated with respect to a malfunction of the high-voltage system. All statements regarding the inventive high-voltage system can likewise be applied to the inventive process. The inventive method therefore advantageously also enables a diagnosis of the functionality of the discharge circuit, in particular by using pre-existing devices/hardware. The voltage profile may also be evaluated with respect to at least one additional function of the high-voltage system and/or the motor vehicle, in particular with respect to controlling an electric motor of the motor vehicle. A pre-existing measuring device with a pre-existing control device may therefore be used to implement an additional function.

As already mentioned, for example, two different types of malfunctions may be detected. For example, a malfunction may be detected when the elapsed time after closing the discharge switching means and until a limit voltage below the output voltage of the high-voltage battery time is reached exceeds a time threshold value. For example, it may be determined whether a discharge is not possible at all or is very slow. Alternatively, advantageously also in addition, the discharge may be interrupted for a predetermined time by controlling the discharge switching means and a malfunction is detected when a voltage is present that is outside a threshold range about the voltage present at the time of the interruption. Such situation would indicate that the discharge is permanently activated.

Like with the high-voltage system, an error message may only be generated with the method when a safety limit value for the number of malfunctions, in particular the number of malfunctions of a particular type, is exceeded. This may happen, for example, when a malfunction of the same type is detected during three consecutive cycles. In this context, as well as in general, the measurement and the evaluation may be performed each time the high-voltage supply is disconnected.

Lastly, the invention also relates to a motor vehicle which is equipped with a high-voltage system according to the invention. All previously made statements also apply to such motor vehicle.

Additional advantages and details of the present invention will become apparent from the exemplary embodiments described below and with reference to the drawing, which show in:

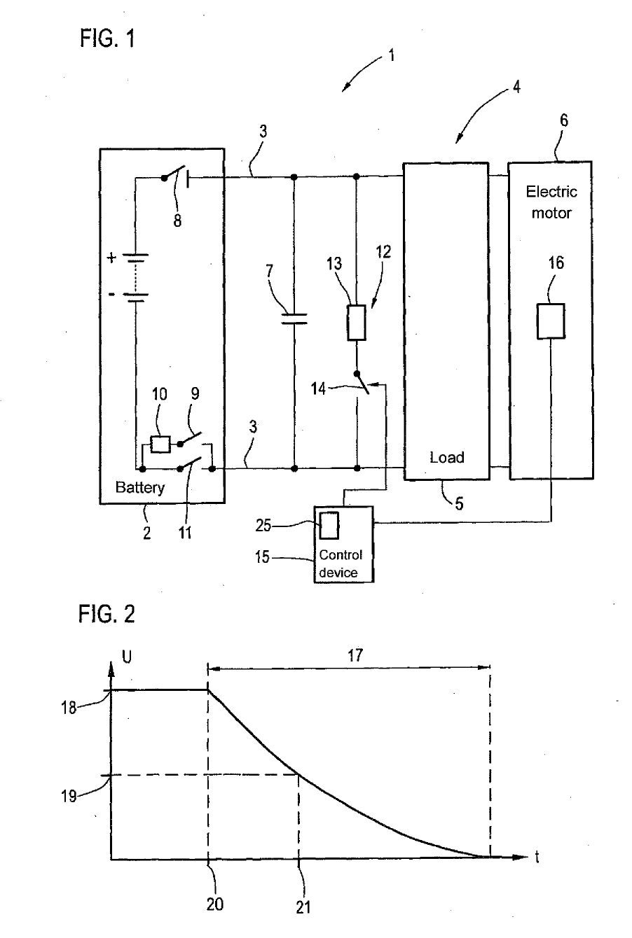

FIG. 1 shows a high-voltage system according to the invention,

FIG. 2 shows a voltage profile during a typical discharge process,

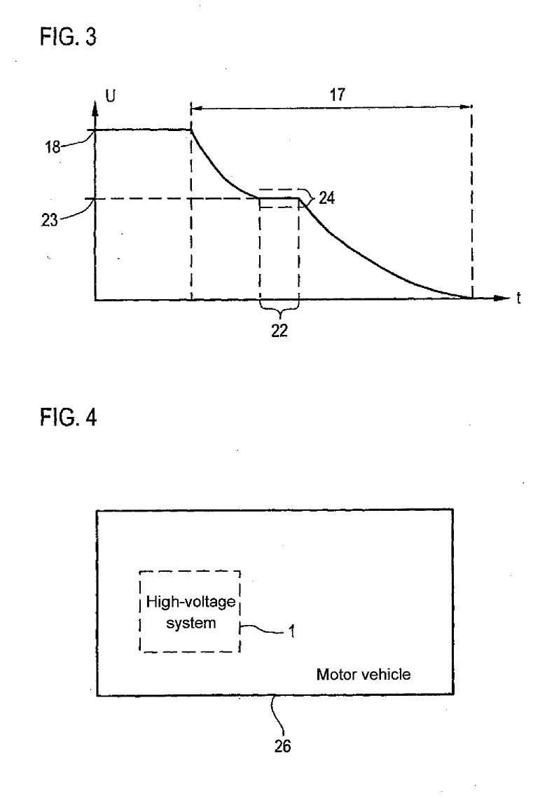

FIG. 3 shows a voltage profile during an interrupted discharge, and

FIG. 4 shows a motor vehicle according to the invention.

FIG. 1 shows a high-voltage system 1 according to the invention. The high-voltage system 1 comprises a high-voltage battery 2, which can be connected via cables 3 to a load generally designated as 4, here specifically a pulse inverter 5, which is connected upstream of an electric motor 6 of the vehicle. The so-formed DC-link circuit also includes a capacitor 7, i.e. a DC-link capacitance.

When the high-voltage supply is switched on, for example, by turning an ignition key or the like, initially a “soft” turn-on is contemplated to controllably charge the capacitor 7. For this purpose, the switching means 8 on the side of the high-voltage battery 2 and the switching means 9 associated with a ballast resistor 10 are closed first. When a minimum voltage is reached, the switching means 11 is closed and the switching means 9 is opened again, so that the load 4 is connected directly to the high-voltage battery 2. The switching means 8, 9 and 11 may be implemented, for example, as contactors.

When the high-voltage battery 2 is disconnected again from the load 4, i.e. a disconnection of the high-voltage supply is initiated, for example, by again turning an ignition key, the switching means 8 and 11 are opened, so that the load is no longer electrically connected to the voltage source, i.e. the high-voltage battery 2. However, a charge may then still remain on the capacitor 7, which should be eliminated to protect personnel.

The high-voltage system 1 therefore also includes a discharge circuit 12 with a discharge resistor 13 and a discharge switching means 14, which can be controlled via a control device 15, for example, after the high-voltage battery 2 has communicated via a vehicle bus, for example a CAN-bus, that the switching means 8 and 11 have been opened. Whereas the discharge resistor is a resistor in the kilo-ohm range, the ballast resistor 10 is a resistor in the ohm range, allowing the charging process to proceed very fast.

The discharge circuit 12 operates to reduce the intermediate circuit voltage remaining on the capacitor 7, after the high-voltage supply has been disconnected, within a short time to a value that is smaller than a voltage that is safe to touch (60 V). In this way, personnel is not endangered by open cables carrying dangerous voltages. To this end, the discharge switching means 14 is closed and the charges of the capacitor 7 are discharged through the discharge resistor 13.

The high-voltage system 1 according to the invention also includes a diagnostic device for detecting malfunctions of the discharge circuit 12, which means that different types of malfunctions can be determined when the functionality of the discharge circuit 12 is not as desired.

To this end, a measuring device 16 configured to measure the applied voltages is arranged within the electric motor 6. Such measuring devices 16 are typically always present, since the control device 15 controls the electric motor 6 via the applied voltages or voltage profiles. In this exemplary embodiment, use is made of the fact that the voltage profile measured with the measuring device 16 correlates with the voltage profile on the capacitor 7. The voltage is thus measured with the measuring device 16 and also supplied to the control device 15 when simultaneously a discharge process occurs via the discharge circuit 12, i.e. when the high-voltage supply is disconnected. The resulting voltage profile recorded during the discharge process is evaluated by the control unit 15 with respect to the types of malfunctions of the discharge circuit 12. This evaluation, i.e. the diagnosis, is made each time the high-voltage supply is disconnected and can be detected, for example, based on a deactivation of the ignition or the like, and is detected in any event, since the control device 15 must always control the discharge switching means 14. Each discharge cycle is thus measured and evaluated.

The evaluation process will now be described in more detail with reference to FIGS. 2 and 3. FIG. 2 shows a typical voltage profile during a discharge process 17, wherein in the diagrams the voltage is plotted against time. The voltage 18 supplied by the high-voltage battery 2 provides an obvious starting point; the voltage typically drops during the discharge process 17 after the discharge switching means 14 are closed. To evaluate the measured voltage profile, it is now proposed to consider the time it takes until a limit voltage below the output voltage 18 of the high-voltage battery voltage 2 is reached. If the high-voltage supply is disconnected at the time 20 and the discharge switching means 14 is closed and if the threshold voltage 19 is attained at the time 21, then the difference between the times 20 and 21 is considered. If this time difference exceeds a threshold time, then a malfunction has occurred. In this way, malfunctions the first type can be detected, wherein a discharge is not possible at all, or at least is very slow. Such a malfunction of the first type may occur, for example, when the discharge switching means 14 can no longer be closed.

In principle, a malfunction of the first type may also occur when the switching means 8 and 11 of the high-voltage battery 2 can no longer be opened. However, it will be assumed that the high-voltage battery 2 sends a corresponding signal via the CAN bus only, when the switching means 8 and 11 are opened, thereby ensuring that the malfunction is not at this location and that in fact a diagnostic of the discharge circuit 12 is performed.

FIG. 3 shows how a malfunction of the second type can be determined. To this end, the control device 15 may interrupt the discharge process 17 for a predetermined time 22 during the discharge process 17 by controlling the discharge switching means 14 such that it is opened for this predetermined time 22. A certain voltage 23 is present at the beginning of this time 22. Within the context of the analysis, the control device 15 now checks if the measured voltage remains during the time 22 within a threshold range 24 about the voltage 23. A voltage measured outside this threshold range, in particular a voltage lower than the lower limit of threshold range 24, indicates a malfunction of the second type. Such malfunction may indicate that the discharge is permanently activated. This could occur, for example, when the discharge switching means 14 is permanently closed.

It should be noted at this point that, of course, both malfunctions may be detected during a discharge process 17, for example, by simply taking into account the time 22 when determining the time threshold value.

When the control device 15 detects a malfunction, this is stored by identifying the type of the malfunction in an internal storage device 25 (FIG. 1). Successively detected malfunctions are added in the memory device 25. An actual error message is outputted by the control device 15 only when a malfunction of a specific type has occurred during several cycles, in the present example during three cycles. This measure debounces the detection of malfunctions. For example, the corresponding entry may be deleted from the storage device 25 whenever a malfunction is not detected in the subsequent cycle; however, predetermined time periods may always be considered, during which only a certain number of malfunctions of a specific type may be allowed to occur.

FIG. 4 shows a schematic diagram of a motor vehicle 26 according to the invention. It includes a high-voltage system 1 according to the invention: The motor vehicle 26 may, for example, be a hybrid vehicle or an electric vehicle.

1-16. (canceled)

17. A high-voltage system for a motor vehicle, comprising
a high-voltage battery having a voltage greater than 60 V and supplying power to at least one load via cables,
at least one switching device for disconnecting the high-voltage battery from the load,
a capacitor connected in parallel with the load,
a discharge circuit for discharging the capacitor, the discharge circuit having a discharge resistor and a discharge switch closing the discharge circuit,
a diagnostic device comprising a measuring device for measuring a voltage profile representative of a voltage profile on the capacitor during a discharge process, and
a control device for evaluating the voltage profile in relation to a malfunction of the discharge circuit, wherein the control device is configured to briefly interrupt the discharge process for a predetermined time by controlling the discharge switch and to detect a malfunction when a voltage outside of a threshold range around a voltage that is present at a time when the discharge process is interrupted is measured.

18. The high-voltage system of claim 17, wherein the load comprises an inverter.

19. The high-voltage system of claim 17, wherein the control device is configured to detect a malfunction, when an elapsed time, after the discharge switch is closed and until a limit voltage below an output voltage of the high-voltage battery is reached, exceeds a time threshold value.

20. The high-voltage system of claim 17, further comprising a storage device for storing a number of malfunctions.

21. The high-voltage system of claim 20, wherein the number of malfunctions is associated with an identical type of malfunctions.

22. The high-voltage system of claim 20, wherein the control device is configured to output an error message when the number of malfunctions exceeds a safety limit value.

23. The high-voltage system of claim 17, wherein the diagnostic device is configured to carry out an evaluation at each disconnection of the high-voltage battery from the load.

24. The high-voltage system of claim 17, wherein the diagnostic device is configured to carry out an evaluation at each deactivation of an ignition.

25. The high-voltage system of claim 17, wherein the control device is configured to the evaluate the voltage profile with respect to at least one additional function of the high-voltage battery or the motor vehicle, or both.

26. The high-voltage system of claim 17, wherein the measuring device measures the voltage profile in an electric motor of the motor vehicle.

27. The high-voltage system of claim 26, wherein the control device is configured to control the electric motor of the vehicle depending the measured voltage profile.

28. The high-voltage system of claim 17, further comprising a ballast resistor connected to an output of the high-voltage battery for controlled charging of the capacitor.

29. A method for diagnosing a high-voltage system for a motor vehicle with a high-voltage battery having a voltage greater than 60 V and supplying power to at least one load via cables, with at least one switch for disconnecting the high-voltage battery from the load, a capacitor connected in parallel with the load, a discharge circuit with a discharge resistor for discharging the capacitor, and a discharge switch which closes the discharge circuit, the method comprising the steps of:
measuring a voltage profile representative of voltage profile across the capacitor during a discharge process of the capacitor,
evaluating the voltage profile in relation to a malfunction of the discharge circuit,
interrupting the discharge process for a predetermined time by controlling the discharge switch, and
detecting a malfunction when measuring a voltage outside of a threshold range around a voltage that is present at a time when the discharge process is interrupted.

30. The method of claim 29, wherein the load comprises an inverter.

31. The method of claim 29, wherein a malfunction is detected, when an elapsed time, after a discharge switch is closed and until a limit voltage below an output voltage of the high-voltage battery is reached, exceeds a time threshold value.

32. The method of claim 29, wherein an error message is generated only when a safety limit value for a number of malfunctions is exceeded.

33. The method of claim 32, wherein an error message is generated only when a safety limit value for a number of malfunctions of identical type is exceeded.

34. The method of claim 29, wherein the measurement and the evaluation are performed each time the high-voltage battery is disconnected.

35. The method of claim 29, wherein the voltage profile is evaluated with respect to at least one additional function of the high-voltage system or the motor vehicle.

36. The method of claim 34, wherein the additional function controls an electric motor of the motor vehicle.

37. A motor vehicle comprising a high-voltage system with a high-voltage system, the high-voltage system comprising
a high-voltage battery having a voltage greater than 60 V and supplying power to at least one load via cables,
at least one switching device for disconnecting the high-voltage battery from the load,
a capacitor connected in parallel with the load,
a discharge circuit for discharging the capacitor, the discharge circuit having a discharge resistor and a discharge switch closing the discharge circuit,
a diagnostic device comprising a measuring device for measuring a voltage profile representative of a voltage profile on the capacitor during a discharge process, and
a control device for evaluating the voltage profile in relation to a malfunction of the discharge circuit, wherein the control device is configured to briefly interrupt the discharge process for a predetermined time by controlling the discharge switch and to detect a malfunction when a voltage outside of a threshold range around a voltage that is present at a time when the discharge process is interrupted is measured.
